(19) United States
(12) Patent Application Publication
(10) Pub. No.: US 2015/0268290 A1
(43) Pub. Date: Sep. 24, 2015

(54) Method for On-Line Diagnosing Gradually-Changing Fault of Electronic Current Transformers

(71) Applicants: STATE GRID CORPORATION OF CHINA (SGCC), Beijing (CN); STATE GRID CHONGQING ELECTRIC POWER CO. ELECTRIC POWER RESEARCH INSTITUTE, Chongqing (CN)

(72) Inventors: Guojun He, Chongqing (CN); Ruilin Xu, Chongqing (CN); Tao Chen, Chongqing (CN); Youqiang Zhang, Chongqing (CN); Hongbin Wang, Chongqing (CN); Jian Luo, Chongqing (CN); Jin Gao, Chongqing (CN); Xiaoyong Zhang, Chongqing (CN); Xiaorui Hu, Chongqing (CN); Jiayong Zhong, Chongqing (CN); Zujian Liu, Chongqing (CN); Shuyou Yao, Chongqing (CN); Hongxin Yu, Chongqing (CN); Yan He, Chongqing (CN); Jie Li, Chongqing (CN); Wei Xiong, Chongqing (CN); Su Wei, Chongqing (CN); Fei Huang, Chongqing (CN); Ruimiao Wang, Chongqing (CN); Kun Jiang, Chongqing (CN); Xin Xu, Chongqing (CN); Te Zhu, Chongqing (CN); Yan Wei, Chongqing (CN)

(21) Appl. No.: 14/436,815

(22) PCT Filed: Oct. 9, 2013
(86) PCT No.: PCT/CN2013/084913

§ 371 Date: Apr. 17, 2015

(30) Foreign Application Priority Data
Oct. 24, 2012 (CN) 201210411341.9

(51) Int. Cl. G01R 31/02

(52) U.S. Cl. CPC G01R 31/027

(57) ABSTRACT

A method for on-line diagnosing gradually-changing fault of electronic current transformers comprises the following steps collecting output signals of electronic transformers of a whole transformer substation, calculating theoretical instantaneous values of the current at the tail ends of power transmission lines and on secondary sides of transformers at every moment, comparing the theoretical instantaneous values with the corresponding collected values, calculating residual errors of the electronic current transformers at the head and tail ends of each power transmission line and the primary and the secondary sides of each transformer respectively, judging whether gradually-changing fault occurs with the electronic current transformers by comparing the residual errors with preset threshold values, and simultaneously performing Kirchhoff detection by injecting current into a busbar to position a fault transformer.

### CROSS-REFERENCE TO RELATED APPLICATIONS

This application claims priority to Chinese patent application No. 201210411341.9, titled “METHOD FOR ON-LINE DIAGNOSING GRADUALLY-CHANGING FAULT OF ELECTRONIC CURRENT TRANSFORMERS” and filed with the State Intellectual Property Office on Oct. 24, 2012, which is hereby incorporated by reference in its entirety.

### FIELD

The disclosure relates to the field of electrical equipment failure detection techniques in the electric power system, and particularly to a gradual failure online diagnosis method for an electronic current transformer.

### BACKGROUND

With the construction and extension smart substations, the application of electronic transformers becomes increasingly widespread. Due to performance deterioration, harsh site environment and other reasons, there is often a measurement error between the output of the electronic transformer running on site and an ideal value thereof, and as a result, the reliability of power supply is reduced. Since the electronic transformer is very different from an electromagnetic transformer in principle, the reliability of the electronic transformer has some new characteristics. For the electronic transformers which are actually working in the power grid, the running time thereof is generally not long, and most of them have a high failure rate and are in the early failure stage of the product. After long-time running in harsh environments, the electronic transformer is no longer stable in performance.

At present, there is no effective online monitoring and failure diagnosis method for a running electronic current transformer. If the status of the electronic current transformer is abnormal, the functions of a secondary device in the substation will be directly affected. Since the failure of the electronic current transformer can not be eliminated, the research on a failure diagnosis method for the electronic current transformer has great realistic meanings.

At present, the research on the reliability of the electronic transformer is limited to the pre-analysis stage, and a verification method is mostly adopted to evaluate the quality of the electronic transformer offline. For a online verification method, it is required for a specific standard current sensor to be connected into the power grid, and standard channels further require additional high-pressure side signal acquisition and processing systems, communications systems and high-pressure side power supplies, and its greatest drawback is that the on-site verification can only be manually performed on a single fixed electronic transformer, which greatly reduces the on-site flexibility. Therefore, this method is not a real-time online condition monitoring method in the real sense. The condition monitoring of the electronic transformer at home still remains at the level of regular power outage maintenance.

With a sudden-change failure diagnosis method for the electronic transformer that is based on signal processing, it is determined whether the failure occurs in a single electronic transformer or in the power grid itself by using wavelet transform to extract a time instant at which the output signal of the electronic transformer suddenly changes and by detecting whether there are signals of two or more electronic transformers which suddenly change at this time instant. This method makes beneficial explorations in diagnosing a sudden-change failure of the electronic transformer, but it is not useful in diagnosing a gradual failure. In a case that the gradual failure occurs in the electronic transformer, failure feature signals have large spans and unobvious local features in time domain, and it is difficult to directly use such signals for failure determination.

As can be seen, the present failure diagnosis research of the electronic current transformer at home and aboard is still in the beginning stage; and especially for the gradual failure diagnosis, the research is nearly blank and no mature theory and method can be used for reference. Provided that there is insufficient research on operation condition recognition of the electronic transformer, and the monitoring thereof still remains in the level of regular power outage maintenance, the technical problem to be solved in the field is how to perform online monitoring on a running electronic current transformer and how to determine whether a gradual failure occurs in the electronic current transformer.

### SUMMARY

For solving the above technical problem, it is provided a gradual failure diagnosis method for an electronic current transformer according to the disclosure, which can achieve gradual failure online diagnosis and can accurately identify and locate the failed electronic current transformer in the smart substation, in conditions that there is no need for additional external hardware detection device and the electronic current transformer is not required to be powered off or out-of-service.

The gradual failure online diagnosis method for the electronic current transformer according to an embodiment of the invention includes:

collecting, at a head of each transmission line of a substation, three-phase current instantaneous signals output by an electronic current transformer and three-phase voltage instantaneous signals output by an electronic voltage transformer;

computing theoretical three-phase current instantaneous values iₒᵤₜ(t) at an end of the transmission line based on the three-phase current instantaneous signals and the three-phase voltage instantaneous signals that are collected at the head of the transmission line;

collecting three-phase current instantaneous signals iₙ(t) output by an electronic current transformer at the end of each transmission line;

computing a first residual εₐ=|iₙ(t)−iₒᵤₜ(t)| between the current transformer at the head of the transmission line and the current transformer at the end of the transmission line based on the three-phase current instantaneous signals collected at the end of the transmission line and the computed theoretical three-phase current instantaneous values, where εₐ represents the residual of an a-th line, and a represents the number of the transmission lines, a=1, 2, 3 . . . ; and

comparing the first residual εₐ with a first preset threshold ε₀, and determining that a gradual failure occurs in the electronic current transformer at the head of the a-th transmission line and in the electronic current transformer at the end of the a-th transmission line if the first residual εₐ is greater than or equal to the first preset threshold ε₀.

Preferably, in a case that it is determined the gradual failure occurs in the electronic current transformer at the head of the a-th transmission line and in the electronic current transformer at the end of the a-th transmission line, the method further includes:

performing a Kirchhoff detection on the three-phase current instantaneous signals of the electronic current transformers of all transmission lines on a bus of the substation, and determining that the electronic current transformer where the gradual failure occurs is located at the head of the a-th transmission line if the vector sum of current flowing into the bus is greater than ε₀, or determining that the electronic current transformer where the gradual failure occurs is located at the end of the a-th transmission line if the vector sum of current flowing into the bus is smaller than or equal to ε₀.

Preferably, the computing theoretical three-phase current instantaneous values iₒᵤₜ at the end of the transmission line based on the three-phase current instantaneous signals and the three-phase voltage instantaneous signals that are collected at the head of the transmission line includes:

computing a positive sequence current component iₘ₁(t), a negative sequence current component iₘ₂(t), and a zero sequence current component iₘ₀(t) at the head of the transmission line based on the three-phase current instantaneous signals collected at the head of the transmission line;

computing a positive sequence voltage component uₘ₁(t), a negative sequence voltage component uₘ₂(t), and a zero sequence voltage component uₘ₀(t) at the head of the transmission line based on the three-phase voltage instantaneous signals collected at the head of the transmission line;

computing a positive sequence current component iⱼₙ₁(t), a negative sequence current component iⱼₙ₂(t), and a zero sequence current component iⱼₙ₀(t) at the end of the transmission line with the following formula (1):

$${i}_{jn} ( t ) = {i}_{m} ( t ) - {Cxu}_{m}^{( 1 )} ( t ) + \frac{1}{2} \times [ {RCx}^{2} {i}_{m}^{( 1 )} ( t ) + {LCx}^{2} {i}_{m}^{( 2 )} ( t ) ] \qquad ( 1 )$$

where R is the equivalent resistance per unit length of the transmission line, and values of R are R1, R2 and R0 for the computations of the positive sequence component, the negative sequence component and the zero sequence component respectively;

L is the equivalent inductance per unit length of the transmission line, and values of L are L1, L2 and L0 for the computations of the positive sequence component, the negative sequence component and the zero sequence component respectively;

C is the equivalent capacitance per unit length of the transmission line, and values of C are C1, C2 and C0 for the computations of the positive sequence component, the negative sequence component and the zero sequence component respectively;

x is the length of the transmission line;

iⱼₙ(t) is a theoretical computation value for the sequence current component at the end of the transmission line, and iⱼₙ(t) is iⱼₙ₁(t) for the positive sequence current component, iⱼₙ₂ for the negative sequence current component and iⱼₙ₀(t) for the zero sequence current component respectively;

iₙ(t) is the sequence current component at the head of the transmission line, and JO is iⱼₙ₁(t) for the positive sequence current component, iₘ₂(t) for the negative sequence current component and iₘ₀(t) for the zero sequence current component;

uₘ⁽¹⁾(t)=(uₘ(t)−uₘ(t−Δt))/Δt, and uₘ(t) is uₘ₁(t) for the positive sequence voltage component, uₘ₂(t) for the negative sequence voltage component and uₘ₀(t) for the zero sequence voltage component;

iₘ⁽¹⁾(t)=[iₘ(t)−iₘ(t−Δt)]/Δt; and

iₘ⁽²⁾(t)=[iₘ(t)−2iₘ(t−Δt)+iₘ(t−2Δt)]/Δt²; and

computing a theoretical current instantaneous value iₒᵤₜ(t) at the end of the transmission line based on the positive sequence current component iⱼₙ₁(t), the negative sequence current component iⱼₙ₂(t) and the zero sequence current component iⱼₙ₀(t) at the end of the transmission line, in which theoretical three-phase current instantaneous values corresponding to iₒᵤₜ(t) are i_{outA}(t), i_{outB}(t) and i_{outC}(t) respectively.

Preferably, both a time interval for collecting the three-phase current instantaneous signals and a time interval for collecting the three-phase voltage instantaneous signals are Δt, and 0.05 ms≦Δt≦0.25 ms.

It is also provided a gradual failure online diagnosis method for an electronic current transformer according to an embodiment of the invention, the method includes:

collecting, at the primary side of each transformer of a substation, three-phase current instantaneous signals output by an electronic current transformer and three-phase voltage instantaneous signals output by an electronic voltage transformer;

computing theoretical three-phase current values i₂ⱼ(t) at the secondary side of the transformer based on the three-phase current instantaneous signals i_{1A}(t), i_{1B}(t), i_{1C}(t); and the three-phase voltage instantaneous signals u_{1A}(t), u_{1B}(t), u_{1C}(t) that are collected at the primary side of the transformer;

collecting three-phase current instantaneous signals i₂(t) output by an electronic current transformer at the secondary side of the transformer;

obtaining a second residual ε_{b}=|i₂(t)−i₂ⱼ(t)| between the current transformer at the primary side of the transformer and the current transformer at secondary side of the transformer based on the three-phase current instantaneous signals i₂(t) collected at secondary side of the transformer and the computed theoretical three-phase current values i₂ⱼ(t) at secondary side, where ε_{b} represents the residual of a b-th transformer, and b represents the number of the transformers, b=1, 2, 3 . . . ; and comparing the second residual ε_{b} with a second preset threshold ε₀₁, and determining that a gradual failure occurs in the electronic current transformer at the primary side of the b-th transformer and in the electronic current transformer at the secondary side of the b-th transformer if the second residual ε_{b} is greater than or equal to the second preset threshold ε₀₁.

Preferably, the computing theoretical three-phase current values i₂ⱼ(t) at the secondary side of the transformer based on the three-phase current instantaneous signals i_{1A}(t); i_{1B}(t); i_{1C}(t) and the three-phase voltage instantaneous signals u_{1A}(t), u_{1B}(t), u_{1C}(t) that are collected at the primary side of the transformer includes:

computing a magnetic flux density increment ΔB(t) of a excitation branch of the transformer with the following formula (2):

$$Δ B ( t ) = \frac{1}{2 {N}_{1} S} [ {u}_{1} ( t - Δ t ) - {r}_{1} {i}_{1} ( t - Δ t ) - {L}_{1 σ} \frac{{i}_{1} ( t - Δ t ) - {i}_{1} ( t - 2 Δ t )}{Δ t} + {u}_{1} ( t ) - {r}_{1} {i}_{1} ( t ) - {L}_{1 σ} \frac{{i}_{1} ( t ) - {i}_{1} ( t - Δ t )}{Δ t} ] Δ t \qquad ( 2 )$$

where u₁(t) is a voltage instantaneous value at the primary side of the transformer, and three-phase voltage instantaneous values corresponding to u₁(t) are u_{1A}(t), u_{1B}(t), u_{1C}(t);
i₁(t) is a current instantaneous value at the primary side of the transformer, and three-phase current instantaneous values corresponding to i₁(t) are i_{1A}(t), i_{1B}(t); i_{1C}(t);
r₁ is the winding resistance at the primary side of the transformer;
L_{1σ} is the winding inductance at the primary side of the transformer;
N₁ is the number of primary windings of the transformer; and
S is the cross-sectional area of ferromagnetic material;

performing iterative solving on the following equation by using the magnetic flux density increment ΔB(t) as a step and by utilizing a four-stage four-order Runge-Kutta method, to compute magnetization M(t) at a time instant t:

$$\frac{d M}{d B} = \frac{{M}_{an} - M + k δ c \frac{d {M}_{an}}{d {H}_{e}}}{{μ}_{0} k δ + {μ}_{0} ( 1 - α ) ( {M}_{an} - M + k δ c \frac{d {M}_{an}}{d {H}_{e}} )} ;$$

$$where \text{:}$$

$$\frac{d {M}_{an}}{d {H}_{e}} = \frac{{M}_{s}}{a} ( \frac{- 1}{{sinh}^{2} ( ( B / {μ}_{0} + ( α - 1 ) M ) / a )} + \frac{1}{{( ( B / {μ}_{0} + ( α - 1 ) M ) / a )}^{2}} ) ;$$

$${M}_{an} = {M}_{s} ( coth ( \frac{B / {μ}_{0} + ( α - 1 ) M}{a} ) - \frac{a}{B / {μ}_{0} + ( α - 1 ) M} ) ;$$

M is the magnetization, Mₛ is saturation magnetization, k is an irreversible hysteresis loss parameter representing a blocking loss effect of the ferromagnetic material, μ₀ is the vacuum permeability, α is an averaging magnetic field coefficient representing the coupling between magnetic domains, a is a parameter representing the shape of an anhysteretic magnetization curve, c is a magnetic domain wall bending coefficient, and

$$δ = \frac{Δ B}{t}$$

is a direction coefficient; and

substituting the magnetic flux density B(t) and the magnetization M(t) at the time instant t into the following formula to compute a theoretical current value at the secondary side of the transformer at the time instant t:

$${i}_{2 j} ( t ) = \frac{{N}_{1}}{{N}_{2}} [ ( B ( t ) / {μ}_{0} - M ( t ) ) l / {N}_{1} - {i}_{1} ( t ) ]$$

where l is the equivalent length of magnetic path, N2 is the number of secondary windings of the transformer, and theoretical three-phase current values corresponding to i₂ⱼ(t) are i_{2jA}(t), i_{2jB}(t) and i_{2jC}(t).

Preferably, after it is determined that the gradual failure occurs in the electronic current transformer at the primary side of the b-th transformer or in the electronic current transformer at the secondary side of the b-th transformer, the method further includes:

performing a Kirchhoff detection on the collected instantaneous values of the electronic current transformers of all branches on a bus, and determining that the electronic current transformer where the gradual failure occurs is located at the bus side of the b-th transformer if the vector sum of current flowing into the bus is greater than ε₀₁, or determining that the electronic current transformer where the gradual failure occurs is located at the non-bus side of the b-th transformer if the vector sum of current flowing into the bus is smaller than or equal to ε₀₁.

Preferably, both a time interval for collecting the three-phase current instantaneous signals and a time interval for collecting the three-phase voltage instantaneous signals are Δt, and 0.05 ms≦Δt≦0.25 ms.

Compared with the conventional art, the disclosure has the following advantageous effects:

in the disclosure, a diagnostic platform is established based on physical and electrical characteristics of primary system elements of the substation, and circuit models for transmission lines and transformers are constructed to make the two ends of an element electrically associated with each other; the computed current value is compared with the output value of the electronic current transformer to obtain residual failure information; and the extracted failure feature reference component is analyzed, to identify the gradual failure of the electronic current transformer. In addition, based on the Kirchhoffs current law constraint on the bus, the failed current transformer can be accurately located. The operation is easy, the calculation accuracy is high, and gradual failures which have large spans and unobvious local features in time domain can be accurately identified. In the disclosure, by utilizing the data collected by the electronic transformer of the primary system itself of the smart substation, the electronic current transformer where the gradual failure occurs can be identified in the substation network, without any additional hardware device; in the disclosure, the online failure diagnosis can be performed on the electronic current transformer in condition that the electronic transformer is not required to be powered off or out-of-service, making the operation of on-site devices unaffected; and the failure threshold can be arbitrarily set as required, making it possible to identify failures at different degrees, and bringing strong flexibility.

### BRIEF DESCRIPTION OF THE DRAWINGS

For more clearly illustrating the technical solutions in embodiments of the invention or in the conventional art, accompany drawings referred to describe the embodiments or the conventional art will be briefly described hereinafter. Apparently, the drawings in the following description are only several embodiments of the invention, and for those skilled in the art, other drawings may be obtained based on these drawings without any creative effort.

FIG. 1 is flow chart of a method according to an embodiment of the invention;

FIG. 2 is a schematic structural diagram showing a distributed parameter circuit model of a transmission line;

FIG. 3 is a circuit diagram of a unit in FIG. 2;

FIG. 4 is a schematic structural diagram showing a transformer model containing excitation branches; and

FIG. 5 is a schematic structural diagram showing a substation in an experimental example of the invention.

### DETAILED DESCRIPTION

The technical solutions in the embodiments of the invention will be described clearly and completely hereinafter in conjunction with the accompany drawings in the embodiments. Apparently, the described embodiments are only a part of the embodiments of the invention, rather than all embodiments. Based on the embodiments, all of other embodiments, made by those skilled in the art without any creative effort, fall into the scope of protection of the disclosure.

For making the above objectives, features and advantages of the disclosure more apparent, the embodiments of the invention will be described in detail in conjunction with the accompany drawings hereinafter.

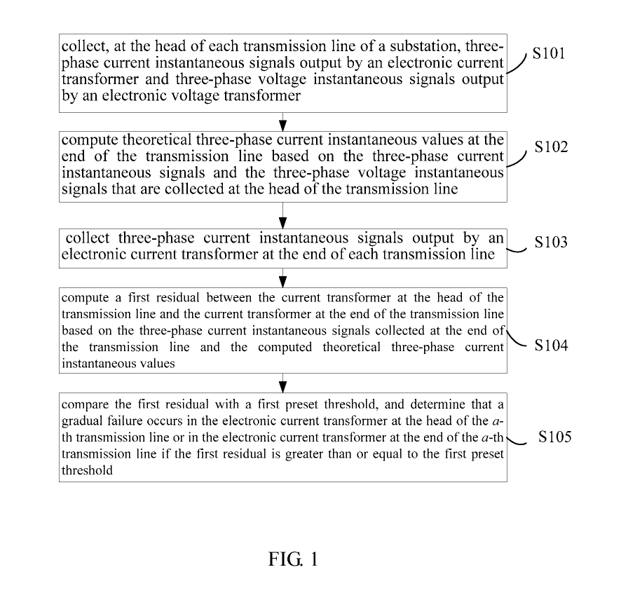

Referring to FIG. 1, a flow chart of a method according to an embodiment of the invention is shown.

An online gradual failure diagnosis method for an electronic current transformer according to the embodiment includes steps S101 to S105.

In S101, three-phase current instantaneous signals output by an electronic current transformer and three-phase voltage instantaneous signals output by an electronic voltage transformer at the head of each transmission line of a substation are collected.

In S102, theoretical three-phase current instantaneous values iₒᵤₜ(t) at the end of the transmission line are computed based on the three-phase current instantaneous signals and the three-phase voltage instantaneous signals that are collected at the head of the transmission line.

In S103, three-phase current instantaneous signals iₙ(t) output by an electronic current transformer at the end of each transmission line are collected.

In S104, a first residual εₐ=|iₙ(t)−iₒᵤₜ(t)| between the current transformer at the head of the transmission line and the current transformer at the end of the transmission line is computed based on the three-phase current instantaneous signals collected at the end of the transmission line and the computed theoretical three-phase current instantaneous values, where εₐ represents the residual of an a-th line, and a represents the number of the transmission lines, a=1, 2, 3 . . . .

In S105, the first residual εₐ is compared with a first preset threshold ε₀, and it is determined that a gradual failure occurs in the electronic current transformer at the head of the a-th transmission line or in the electronic current transformer at the end of the a-th transmission line if the first residual εₐ is greater than or equal to the first preset threshold ε₀.

In the disclosure, a diagnostic platform is established based on physical and electrical characteristics of primary system elements of the substation, and circuit models for transmission lines and transformers are constructed to make the two ends of an element electrically associated with each other; the computed current value is compared with the output value of the electronic current transformer to obtain residual failure information; and the extracted failure feature reference component is analyzed, to identify the gradual failure of the electronic current transformer. In addition, based on the Kirchhoffs current law constraint on the bus, the failed current transformer can be accurately located. The operation is easy, the calculation accuracy is high, and gradual failures which have large spans and unobvious local features in time domain can be accurately identified. In the disclosure, by utilizing the data collected by the electronic transformer of the primary system itself of the smart substation, the electronic current transformer where the gradual failure occurs can be identified in the substation network, without any additional hardware device; in the disclosure, the online failure diagnosis can be performed on the electronic current transformer in condition that the electronic current transformer is not required to be powered off or out-of-service, making the operation of field devices unaffected; and the failure threshold can be arbitrarily set as required, making it possible to identify failures at different degrees, and bringing strong flexibility.

In the following, the implementation process of the disclosure will be described in detail.

Specifically, the disclosure includes steps as follows.

(1) Output signals of electronic transformers in the whole substation are collected.

\textcircled{1} ED Three-phase current instantaneous signals output by an electronic current transformer and three-phase voltage instantaneous signals output by an electronic voltage transformer at the head of each transmission line of the substation are collected in a real time manner; a current instantaneous signal iₙ(t) output by an electronic current transformer at the end of each transmission line is collected, the three-phase current instantaneous signals corresponding to iₙ(t) are i_{nA}(t), i_{nB}(t), i_{nC}(t); and all time intervals for acquiring the electrical signals are Δt, and 0.05 ms≦Δt≦0.25 ms.

\textcircled{2} Three-phase current instantaneous signals i_{1A}(t), i_{1B}(t), i_{1C}(t) output by an electronic current transformer and three-phase voltage instantaneous signals u_{1A}(t), u_{1B}(t), u_{1C}(t) output by an electronic voltage transformer at the primary side of each transformer of the substation are collected in a real time manner; meanwhile, a current instantaneous signal i₂(t) output by an electronic current transformer at the secondary side of the transformer is collected, the three-phase current instantaneous signals corresponding to i₂(t) are i_{2A}(t), i_{2B}(t), i_{2C}(t); and all time intervals for acquiring the electrical signals are Δt, and 0.05 ms≦Δt≦0.25 ms.

(2) A theoretical current instantaneous value at the end of the transmission line and a theoretical current instantaneous value at the secondary side of the transformer at a time instant t are computed.

\textcircled{1} A theoretical current instantaneous value at the end of the transmission line at a time instant t is computed.

A positive sequence current component iₘ₁(t), a negative sequence current component iₘ₂(t), a zero sequence current component iₘ₀(t), a positive sequence voltage component uₘ₁(t), a negative sequence voltage component uₘ₂(t), and a zero sequence voltage component uₘ₀(t) at the head of the transmission line at the time instant t are computed, based on the three-phase current instantaneous signals and the three-phase voltage instantaneous signals at the head of the transmission line at the time instant t that are acquired in step (1); and these components are substituted into the following formula to compute a positive sequence current component iⱼₙ₁(t), a negative sequence current component iⱼₙ₂(t), and a zero sequence current component iⱼₙ₀(t) at the end of the transmission line:

$${i}_{jn} ( t ) = {i}_{m} ( t ) - {Cxu}_{m}^{( 1 )} ( t ) + \frac{1}{2} \times [ {RCx}^{2} {i}_{m}^{( 1 )} ( t ) + {LCx}^{2} {i}_{m}^{( 2 )} ( t ) ]$$

where in the above formula:

R is the equivalent resistance per unit length of the transmission line, and values of R are R1, R2 and R0 for the computations of the positive sequence component, the negative sequence component and the zero sequence component respectively;

L is the equivalent inductance per unit length of the transmission line, and values of L are L1, L2 and L0 for the computations of the positive sequence component, the negative sequence component and the zero sequence component respectively;

C is the equivalent capacitance per unit length of the transmission line, and values of C are C1, C2 and C0 for the computations of the positive sequence component, the negative sequence component and the zero sequence component respectively;

x is the length of the transmission line;

iⱼₙ(t) is a theoretical computation value for the sequence current component at the end of the transmission line, and iⱼₙ(t) is iⱼₙ₁(t) for the positive sequence current component, iⱼₙ₂(t) for the negative sequence current component and iⱼₙ₀(t) for the zero sequence current component respectively;

iₘ(t) is the sequence current component at the head of the transmission line, and iₘ(t) is iₘ₁(t) for the positive sequence current component, iₘ₂(t) for the negative sequence current component and iₘ₀(t) for the zero sequence current component;

uₘ⁽¹⁾(t)=(uₘ(t)−uₘ(t−Δt))/Δt, and uₘ(t) is uₘ₁(t) for the positive sequence voltage component, uₘ₂(t) for the negative sequence voltage component and uₘ₀(t) for the zero sequence voltage component;

iₘ⁽¹⁾(t)=[iₘ(t)−iₘ(t−Δt)]/Δt; and

iₘ⁽²⁾(t)=[iₘ(t)−2iₘ(t−Δt)+iₘ(t−2Δt)]/Δt²; and

a theoretical current instantaneous value iₒᵤₜ(t) at the end of the transmission line is computed based on the positive sequence current component iⱼₙ₁(t), the negative sequence current component iⱼₙ₂(t) and the zero sequence current component iⱼₙ₀(t) at the end of the transmission line at the time instant t that are obtained by computation, in which theoretical three-phase current instantaneous values corresponding to iₒᵤₜ(t) are i_{outA}(t), i_{outB}(t) and i_{outC}(t) respectively.

\textcircled{2} A theoretical current instantaneous value at the secondary side of the transformer at a time instant t is computed.

The three-phase current instantaneous signals i_{1A}(t), i_{1B}(t), i_{1C}(t) and the three-phase voltage instantaneous signals u_{1A}(t), u_{1B}(t), u_{1C}(t) at the primary side of the transformer at the time instant t that are acquired in step (1) are substituted into the following formula to compute a magnetic flux density increment AB(t) of a excitation branch of the transformer:

$$Δ B ( t ) = \frac{1}{2 {N}_{1} S} [ {u}_{1} ( t - Δ t ) - {r}_{1} {i}_{1} ( t - Δ t ) - {L}_{1 σ} \frac{{i}_{1} ( t - Δ t ) - {i}_{1} ( t - 2 Δ t )}{Δ t} + {u}_{1} ( t ) - {r}_{1} {i}_{1} ( t ) - {L}_{1 σ} \frac{{i}_{1} ( t ) - {i}_{1} ( t - Δ t )}{Δ t} ] Δ t$$

where:

u₁(t) is a voltage instantaneous value at the primary side of the transformer, and three-phase voltage instantaneous values corresponding to u₁(t) are u_{1A}(t), u_{1B}(t), u_{1C}(t);

i₁(t) is a current instantaneous value at the primary side of the transformer, and three-phase current instantaneous values corresponding to i₁(t) are i_{1A}(t), i_{1B}(t), i_{1C}(t);

r₁ is the winding resistance at the primary side of the transformer;

L_{1σ} is the winding inductance at the primary side of the transformer;

N₁ is the number of primary windings of the transformer; and

S is the cross-sectional area of ferromagnetic material;

iterative solving is performed on the following equation by using the magnetic flux density increment ΔB(t) as a step and by utilizing a four-stage four-order Runge-Kutta method, to compute magnetization M(t) at the time instant t:

$$\frac{d M}{d B} = \frac{{M}_{an} - M + k δ c \frac{d {M}_{an}}{d {H}_{e}}}{{μ}_{0} k δ + {μ}_{0} ( 1 - α ) ( {M}_{an} - M + k δ c \frac{d {M}_{an}}{d {H}_{e}} )}$$

$$where \text{:}$$

$$\frac{d {M}_{an}}{d {H}_{e}} = \frac{{M}_{s}}{a} ( \frac{- 1}{{sinh}^{2} ( ( B / {μ}_{0} + ( α - 1 ) M ) / a )} + \frac{1}{{( ( B / {μ}_{0} + ( α - 1 ) M ) / a )}^{2}} ) ;$$

$${M}_{an} = {M}_{s} ( coth ( \frac{B / {μ}_{0} + ( α - 1 ) M}{a} ) - \frac{a}{B / {μ}_{0} + ( α - 1 ) M} ) ;$$

M is the magnetization, Mₛ is saturation magnetization, k is an irreversible hysteresis loss parameter representing a blocking loss effect of the ferromagnetic material, μ₀ is the vacuum permeability, α is an averaging magnetic field coefficient representing the coupling between magnetic domains, a is a parameter representing the shape of an anhysteretic magnetization curve, c is a magnetic domain wall bending coefficient, and

$$δ = \frac{Δ B}{t}$$

is a direction coefficient; and

the magnetic flux density B(t) and the magnetization M(t) at the time instant t are substituted into the following formula to compute a theoretical current value at the secondary side of the transformer at the time instant t:

$${i}_{2 j} ( t ) = \frac{{N}_{1}}{{N}_{2}} [ ( B ( t ) / {μ}_{0} - M ( t ) ) l / {N}_{1} - {i}_{1} ( t ) ]$$

where l is the equivalent length of magnetic path, N2 is the number of secondary windings of the transformer, and theoretical three-phase current values corresponding to i₂ⱼ(t) are i_{2jA} i_{2jB}(t) and i_{2jC}(t).

(3) A residual εₐ between the electronic current transformer at the head of the transmission line and the electronic current transformer at the end of the transmission line and a residual ε_{b} between the electronic current transformer at the primary side of the transformer and the electronic current transformer at secondary side of the transformer are computed respectively:

\textcircled{1} a residual εₐ=|iₙ(t)−iₒᵤₜ(t)| between the current transformer at the head of the transmission line and the current transformer at the end of the transmission line is computed, where εₐ represents the residual of an a-th line, and a represents the number of the transmission lines, a=1, 2, 3 . . . ; and

\textcircled{2} a residual ε_{b}=|i₂(t)−i₂ⱼ(t)| between the current transformer at the primary side of the transformer and the current transformer at secondary side of the transformer is computed, where ε_{b} represents the residual of a b-th transformer, and b represents the number of the transformers, b=1, 2, 3 . . . .

(4) The gradual failure of the electronic current transformer is determined:

\textcircled{1} in a case that εₐ<ε₀ and ε_{b}<ε₀, ε₀ is the preset threshold, it is determined that no gradual failure occurs in the electronic current transformer of the primary system of the substation, and then t+Δt is used as a new time instant t to perform step (2);

\textcircled{2} in a case that εₐ>ε₀, it is determined that a gradual failure occurs in the electronic current transformer at the head of the a-th transmission line or in the electronic current transformer at the end of the a-th transmission line in the substation, and then step (5) is performed; and

\textcircled{3} in a case that ε_{b}>ε₀, it is determined that a gradual failure occurs in the electronic current transformer at the primary side of the b-th transformer or in the electronic current transformer at the secondary side of the b-th transformer in the substation, and then step (6) is performed.

(5) A Kirchhoff detection is performed on the collected instantaneous values of the electronic current transformers of all branches on the bus of the substation, and it is determined that the electronic current transformer where the gradual failure occurs is located at the head of the a-th transmission line if the vector sum of current flowing into the bus is greater than ε₀, or it is determined that the electronic current transformer where the gradual failure occurs is located at the end of the a-th transmission line if the vector sum of current flowing into the bus is smaller than or equal to ε₀; and then t+Δt is used as a new time instant t to perform step (2).

(6) A Kirchhoff detection is performed on the collected instantaneous values of the electronic current transformers of all branches on the bus of the substation, and it is determined that the electronic current transformer where the gradual failure occurs is located at the bus side of the b-th transformer if the vector sum of current flowing into the bus is greater than ε₀, or it is determined that the electronic current transformer where the gradual failure occurs is located at the non-bus side of the b-th transformer if the vector sum of current flowing into the bus is smaller than or equal to ε₀; and then t+Δt is used as a new time instant t to perform step (2).

Steps (2), (3), (4), (5) and (6) are repeatedly performed in this way, to achieve the object that the gradual failure of each electronic current transformer in the substation is diagnosed online in a real time manner.

In the disclosure, a diagnostic platform is established based on physical electrical characteristics of primary system elements of the substation, and circuit models for transmission lines and transformers are constructed to make the two ends of an element electrically associated with each other; the computed current value is compared with the output value of the electronic current transformer to obtain residual failure information; and the extracted failure feature reference component is analyzed, to identify the gradual failure of the electronic current transformer. In addition, based on the Kirchhoff's current law constraint on the bus, the failed current transformer can be accurately located.

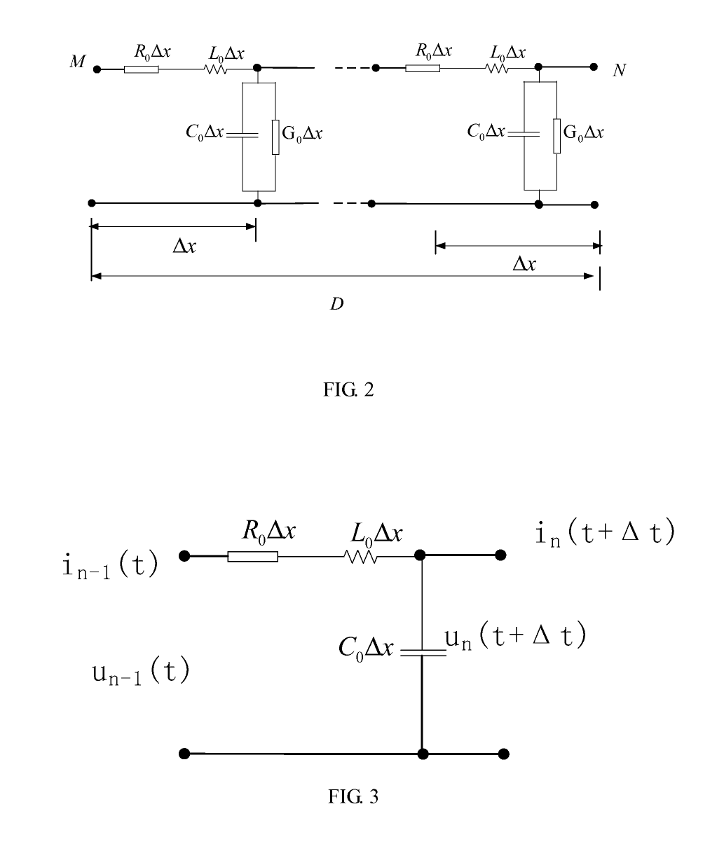

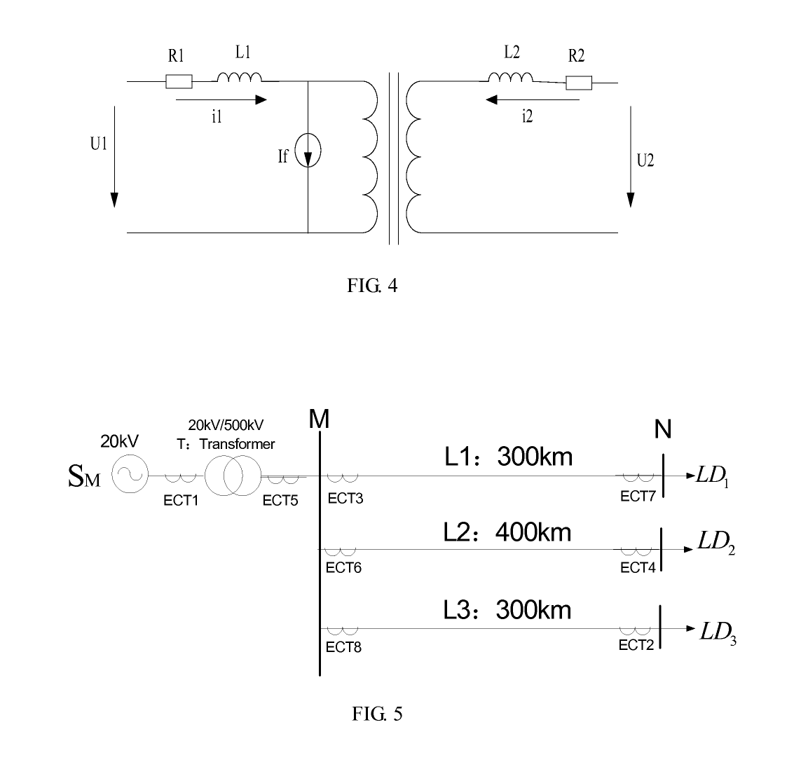

In the disclosure, the transmission line is totally equivalent to a circuit model formed by an infinite number of units that are in series with each other, as shown in FIG. 2. Each unit is composed of a resistor, an inductor and a capacitor, as shown in FIG. 3. The basic idea is that: a circuit parameter differential equation is established for each unit, superposition and derivation are repeatedly performed on each differential equation, and then the current value at each point along the line of the equivalent circuit model can be calculated. Then based on wave principle and taking current zero-passing points at the two ends of an ultra high voltage transmission line as common standards, relatively synchronous time processing sample values are used to present the propagation process of the electromagnetic wave along the line in the form of circuit, and a relationship is obtained that the current at any point on the distributed parameter line is a function of distance x and time t. Meanwhile, a transformer circuit equation is combined, and a transformer model considering ferromagnetic hysteresis as shown in FIG. 4 is established by electromagnetic coupling, thereby establishing a current electrical contact between the two ends of the transformer element. In this way, the current instantaneous value at the secondary side of the transformer may be accurately computed based on the voltage sample value and the current sample value at primary side of the transformer.

For the electronic current transformer in the smart substation, the output current signal under normal circumstances must meet two constraints:

a: electrical characteristic constraints of the primary system element; and

b: the Kirchhoffs current law constraint on the bus.

The smart substation is an integer formed by transformers, the bus, transmission lines and other primary system electrical elements in a certain form, and the electrical operating characteristics of the substation are subject to the physical characteristic constraints of the elements and the Kirchhoffs current law constraint on the bus. In the disclosure, based on the current sample value and the voltage sample value at one end of the transmission line or the current sample value and the voltage sample value at one end of the transformer, the current instantaneous value at the other end may be computed accurately, and the relative error is completely controlled to be smaller than 1% as required; and the computed current instantaneous value is compared with the current sample value at that end, to extract the failure feature of the electronic current transformer; and then the failed electronic current transformer in the substation may be accurately identified based on the Kirchhoffs current law constraint.

Now, the disclosure is further illustrated in combination with experimental examples.

A 500 kV substation is used in the experimental examples, the structure of the substation is shown in FIG. 5, and specific parameters are as follows:

parameters of the transmission line:
1. resistance: R1=R2=0.02083 Ω/km, R0=0.300 Ω/km;
2. inductance: L1=L2=8.984 mH/km, L0=3.159 mH/km
3. capacitance: C1=C2=0.0129 μF/km, C0=0.010 μF/km;
4. angular frequency: ω=2πf≈314 (rad/s); and
5. the full-length of three transmission lines are respectively 300 km, 400 km, 300 km; and
parameters of the transformer:
1. rated voltage: 24 kV 512.5 kV;
2. rated capacity: 223 MVA;
3. the number of windings: 35/715;
4. high voltage winding resistance: 0.7905Ω;
5. low voltage winding resistance: 0.0029Ω;
6. short-circuit impedance percentage: 16.54%;
7. core diameter: 1200 mm;
8. core cross-sectional area: 9343 cm²;
9. equivalent length of magnetic path: 10.87 m; and
10. hysteresis loop parameters: a=6.5 A/m, α=1.49×10⁻⁵, M_{S}=1.48×10⁶ A/m, k=8.6 A/m, c=0.1.

From Mar. 7, 2011 to Feb. 19, 2012, online monitoring and gradual failure diagnosis are performed on the electronic current transformers in the above substation, in which ε₀ is set as 2% of the rated current I0, and Δt=0.25 ms.

### Experimental Example 1

### Mar. 7, 2011, and the Monitoring Data is Shown in Table 1 Below

TABLE 1
Comparison of residuals

| Residual | Corresponding | Sequence of residual/rated current (εₐ/I₀ or ε_{b}/I₀) | | | | | | | | | |
|---|---|---|---|---|---|---|---|---|---|---|---|
| term | element | 1 | 2 | 3 | 4 | 5 | 6 | 7 | 8 | 9 | 10 |
| εₐ₁ | Transformer | 0.000 | 0.001 | 0.003 | 0.002 | 0.001 | 0.002 | 0.002 | 0.003 | 0.002 | 0.001 |
| ε_{b1} | Line 1 | 0.000 | 0.001 | 0.001 | 0.001 | 0.001 | 0.001 | 0.003 | 0.002 | 0.001 | 0.001 |
| ε_{b2} | Line 2 | 0.003 | 0.002 | 0.002 | 0.001 | 0.003 | 0.003 | 0.002 | 0.005 | 0.003 | 0.002 |
| ε_{b3} | Line 3 | 0.001 | 0.000 | 0.001 | 0.001 | 0.001 | 0.002 | 0.001 | 0.001 | 0.000 | 0.001 |

As illustrated in Table 1, the residual of each transmission line and the residual of the transformer are smaller than ε₀, indicating that no gradual failure occurs in the electronic current transformers of the substation. In onsite detection, there is no failure indeed. Therefore, it proves that the determination is right, and the experimental results verify the accuracy of the failure diagnosis method for the electronic current transformer according to the disclosure.

### Experimental Example 2

### Jun. 28, 2011, and the Monitoring Data is Shown in Table 2 Below

TABLE 2
Comparison of residuals

| Residual | Corresponding | Sequence of residual/rated current (εₐ/I₀ or ε_{b}/I₀) | | | | | | | | | |
|---|---|---|---|---|---|---|---|---|---|---|---|
| term | element | 1 | 2 | 3 | 4 | 5 | 6 | 7 | 8 | 9 | 10 |
| εₐ₁ | Transformer | 0.007 | 0.004 | 0.006 | 0.002 | 0.001 | 0.001 | 0.003 | 0.005 | 0.002 | 0.004 |
| ε_{b1} | Line 1 | 0.014 | 0.017 | 0.021 | 0.023 | 0.024 | 0.025 | 0.026 | 0.025 | 0.026 | 0.027 |
| ε_{b2} | Line 2 | 0.003 | 0.001 | 0.002 | 0.004 | 0.005 | 0.003 | 0.002 | 0.004 | 0.006 | 0.007 |
| ε_{b3} | Line 3 | 0.001 | 0.004 | 0.002 | 0.001 | 0.003 | 0.006 | 0.004 | 0.009 | 0.003 | 0.001 |

As illustrated in Table 2, for line 1, from the third sample point, the residual ε_{b1} is 0.021I₀, 0.023I₀, 0.024I₀, 0.025I₀, 0.026I₀, 0.025I₀, 0.026I₀ and 0.027I₀ respectively, each of these residuals is greater than the preset threshold ε₀; however, the computed residuals of other lines and the transformer are not greater than ε₀, indicating that a gradual failure occurs in the electronic current transformer of line 1, and no gradual failure occurs in the electronic current transformers of line 2, line 3 and the transformer. A Kirchhoff detection is performed on the sampled instantaneous values of the electronic current transformers of all branches on the bus of the substation, and the detection result is greater than 0.027I₀ that is, the vector sum of current flowing into the bus is greater than ε₀, indicating that the electronic current transformer where the gradual failure occurs is located at the head of line 1, i.e., ECT3. In this case, the electronic current transformer ECT3 is actually inspected on-site, and it is found that the electronic current transformer indeed fails. Therefore, it proves that the determination is right, and the experimental results verify the accuracy of the failure diagnosis method for the electronic current transformer according to the disclosure.

### Experimental Example 3

### Aug. 16, 2011, and the Monitoring Data is Shown in Table 3 Below

TABLE 3
Comparison of residuals

| Residual | Corresponding | Sequence of residual/rated current (εₐ/I₀ or ε_{b}/I₀) | | | | | | | | | |
|---|---|---|---|---|---|---|---|---|---|---|---|
| term | element | 1 | 2 | 3 | 4 | 5 | 6 | 7 | 8 | 9 | 10 |
| εₐ₁ | Transformer | 0.004 | 0.002 | 0.005 | 0.003 | 0.001 | 0.002 | 0.003 | 0.004 | 0.002 | 0.003 |
| ε_{b1} | Line 1 | 0.002 | 0.001 | 0.001 | 0.001 | 0.002 | 0.004 | 0.003 | 0.005 | 0.001 | 0.001 |
| ε_{b2} | Line 2 | 0.001 | 0.001 | 0.007 | 0.003 | 0.002 | 0.005 | 0.009 | 0.007 | 0.006 | 0.003 |
| ε_{b3} | Line 3 | 0.015 | 0.019 | 0.020 | 0.022 | 0.021 | 0.022 | 0.023 | 0.025 | 0.027 | 0.026 |

As illustrated in Table 3, for Line 3, from the fourth sample point, the residual ε_{b3} is 0.022I₀, 0.021I₀, 0.022I₀, 0.023I₀, 0.025I₀, 0.027I₀ and 0.026I₀ respectively, each of these residuals is greater than the preset threshold ε₀; however, the computed residuals of other lines and the transformer are not greater than ε₀, indicating that a gradual failure occurs in the electronic current transformer of line 3, and no gradual failure occurs in the electronic current transformers of line 1, line 2 and the transformer. A Kirchhoff detection is performed on the sampled instantaneous values of the electronic current transformers of all branches on the bus of the substation, and the detection result is smaller than ε₀, that is, the vector sum of current flowing into the bus is smaller than ε₀, indicating that the electronic current transformer where the gradual failure occurs is located at the end of line 3, i.e., ECT2. In this case, the electronic current transformer ECT2 is actually inspected on-site, and it is found that the electronic current transformer indeed fails. Therefore, it proves that the determination is right, and the experimental results verify the accuracy of the failure diagnosis method for the electronic current transformer according to the disclosure.

### Experimental example 4

### Dec. 21, 2011, and the Monitoring Data is Shown in Table 4 Below

TABLE 4
Comparison of residuals

| Residual | Corresponding | Sequence of residual/rated current (εₐ/I₀ or ε_{b}/I₀) | | | | | | | | | |
|---|---|---|---|---|---|---|---|---|---|---|---|
| term | element | 1 | 2 | 3 | 4 | 5 | 6 | 7 | 8 | 9 | 10 |
| εₐ₁ | Transformer | 0.018 | 0.022 | 0.023 | 0.025 | 0.026 | 0.028 | 0.027 | 0.029 | 0.030 | 0.031 |
| ε_{b1} | Line 1 | 0.001 | 0.002 | 0.001 | 0.001 | 0.003 | 0.002 | 0.001 | 0.001 | 0.002 | 0.001 |
| ε_{b2} | Line 2 | 0.002 | 0.002 | 0.001 | 0.003 | 0.004 | 0.001 | 0.003 | 0.004 | 0.006 | 0.005 |
| ε_{b3} | Line 3 | 0.005 | 0.004 | 0.002 | 0.001 | 0.003 | 0.002 | 0.002 | 0.002 | 0.001 | 0.001 |

As illustrated in Table 4, for the transformer, from the second sample point, the residual εₐ₁ is 0.022I₀, 0.023I₀, 0.025I₀, 0.026I₀, 0.028I₀, 0.027I₀, 0.029I₀, 0.0030I₀ and 0.031I₀ respectively, each of these residuals is greater than the preset threshold ε₀; however, the computed residuals of individual lines are not greater than ε₀, indicating that a gradual failure occurs in the electronic current transformer of the transformer, and no gradual failure occurs in the electronic current transformers of line 1, line 2 and line 3. A Kirchhoff detection is performed on the sampled instantaneous values of the electronic current transformers of all branches on the bus of the substation, and the detection result is greater than ε₀, that is, the vector sum of current flowing into the bus is greater than ε₀, indicating that the electronic current transformer where the gradual failure occurs is located at the bus side of the transformer, i.e., ECT5. In this case, the electronic current transformer ECT5 is actually inspected on site, and it is found that the electronic current transformer indeed fails. Therefore, it proves that the determination is right, and the experimental results verify the accuracy of the failure diagnosis method for the electronic current transformer according to the disclosure.

### Experimental Example 5

### Jan. 30, 2012, and the Monitoring Data is Shown in Table 5 Below

TABLE 5
Comparison of residuals

| Residual | Corresponding | Sequence of residual/rated current (εₐ/I₀ or ε_{b}/I₀) | | | | | | | | | |
|---|---|---|---|---|---|---|---|---|---|---|---|
| term | element | 1 | 2 | 3 | 4 | 5 | 6 | 7 | 8 | 9 | 10 |
| εₐ₁ | Transformer | 0.013 | 0.015 | 0.018 | 0.019 | 0.022 | 0.023 | 0.025 | 0.026 | 0.027 | 0.029 |
| ε_{b1} | Line 1 | 0.002 | 0.001 | 0.001 | 0.003 | 0.005 | 0.004 | 0.002 | 0.003 | 0.001 | 0.002 |
| ε_{b2} | Line 2 | 0.001 | 0.003 | 0.001 | 0.003 | 0.004 | 0.003 | 0.003 | 0.002 | 0.004 | 0.003 |
| ε_{b3} | Line 3 | 0.007 | 0.003 | 0.005 | 0.003 | 0.002 | 0.002 | 0.001 | 0.003 | 0.001 | 0.001 |

As illustrated in Table 5, for the transformer, from the fifth sample point, the residual εₐ₁ is 0.022I₀, 0.023I₀, 0.025I₀, 0.026I₀, 0.027I₀ and 0.029I₀ respectively, each of these residuals is greater than the preset threshold ε₀; however, the computed residuals of individual lines are not greater than ε₀, indicating that a gradual failure occurs in the electronic current transformer of the transformer, and no gradual failure occurs in the electronic current transformers of line 1, line 2 and line 3. A Kirchhoff detection is performed on the sampled instantaneous values of the electronic current transformers of all branches on the bus of the substation, and the detection result is smaller than ε₀, that is, the vector sum of current flowing into the bus is smaller than ε₀, indicating that the electronic current transformer where the gradual failure occurs is located at the non-bus side of the transformer, i.e., ECT1. In this case, the electronic current transformer ECT1 is actually inspected on-site, and it is found that the electronic current transformer indeed fails. Therefore, it proves that the determination is right, and the experimental results verify the accuracy of the failure diagnosis method for the electronic current transformer according to the disclosure.

In the above description, just some preferable embodiments are illustrated, and they should not be interpreted as liming the disclosure in any from. Although the preferable embodiments of the invention have been disclosed above, they are not intended to limit the disclosure. Any one of those skilled in the art can make many possible variations and modifications to the technical solutions of the disclosure or make equivalent embodiments thereto based on the method and technical provisions described above, without departing from the scope of the technical solutions of the disclosure. Therefore, any simple modification, equivalent variation and change, made to the above embodiments based on the technical nature of the disclosure without departing from the content of the technical solutions of the disclosure, still falls into the scope of protection of the disclosure.

1. A gradual failure online diagnosis method for an electronic current transformer, comprising:
collecting, at the head of each transmission line of a substation, three-phase current instantaneous signals output by an electronic current transformer and three-phase voltage instantaneous signals output by an electronic voltage transformer;
computing theoretical three-phase current instantaneous values iₒᵤₜ(t) at the end of the transmission line based on the three-phase current instantaneous signals and the three-phase voltage instantaneous signals that are collected at the head of the transmission line;
collecting three-phase current instantaneous signals iₙ(t) output by an electronic current transformer at the end of each transmission line;
computing a first residual εₐ=|iₙ(t)−iₒᵤₜ(t)| between the current transformer at the head of the transmission line and the current transformer at the end of the transmission line based on the three-phase current instantaneous signals collected at the end of the transmission line and the computed theoretical three-phase current instantaneous values, wherein εₐ represents the residual of an a-th line, and a represents the number of the transmission lines, a=1, 2, 3 . . . ; and
comparing the first residual εₐ with a first preset threshold ε₀, and determining that a gradual failure occurs in the electronic current transformer at the head of the a-th transmission line or in the electronic current transformer at the end of the a-th transmission line if the first residual εₐ is greater than or equal to the first preset threshold ε₀.

2. The gradual failure online diagnosis method for the electronic current transformer according to claim 1, wherein in a case that it is determined the gradual failure occurs in the electronic current transformer at the head of the a-th transmission line or in the electronic current transformer at the end of the a-th transmission line, the method further comprises:
performing a Kirchhoff detection on the three-phase current instantaneous signals of the electronic current transformers of all transmission lines on a bus of the substation, and determining that the electronic current transformer where the gradual failure occurs is located at the head of the a-th transmission line if the vector sum of current flowing into the bus is greater than ε₀, or determining that the electronic current transformer where the gradual failure occurs is located at the end of the a-th transmission line if the vector sum of current flowing into the bus is smaller than or equal to ε₀.

3. The gradual failure online diagnosis method for the electronic current transformer according to claim 1, wherein the computing theoretical three-phase current instantaneous values iₒᵤₜ(t) at the end of the transmission line based on the three-phase current instantaneous signals and the three-phase voltage instantaneous signals that are collected at the head of the transmission line comprises:
computing a positive sequence current component iₘ₁(t), a negative sequence current component iₘ₂(t), and a zero sequence current component iₘ₀(t) at the head of the transmission line based on the three-phase current instantaneous signals collected at the head of the transmission line;
computing a positive sequence voltage component uₘ₁(t), a negative sequence voltage component uₘ₂(t), and a zero sequence voltage component uₘ₀(t) at the head of the transmission line based on the three-phase voltage instantaneous signals collected at the head of the transmission line;
computing a positive sequence current component iⱼₙ₁(t), a negative sequence current component iⱼₙ₂(t), and a zero sequence current component iⱼₙ₀(t) at the end of the transmission line with the following formula (1):
$${i}_{jn} ( t ) = {i}_{m} ( t ) - {Cxu}_{m}^{( 1 )} ( t ) + \frac{1}{2} \times [ {RCx}^{2} {i}_{m}^{( 1 )} ( t ) + {LCx}^{2} {i}_{m}^{( 2 )} ( t ) ] \qquad ( 1 )$$
where R is the equivalent resistance per unit length of the transmission line, and values of R are R1, R2 and R0 for the computations of the positive sequence component, the negative sequence component and the zero sequence component respectively;
L is the equivalent inductance per unit length of the transmission line, and values of L are L1, L2 and L0 for the computations of the positive sequence component, the negative sequence component and the zero sequence component respectively;
C is the equivalent capacitance per unit length of the transmission line, and values of C are C1, C2 and C0 for the computations of the positive sequence component, the negative sequence component and the zero sequence component respectively;
x is the length of the transmission line;
iⱼₙ(t) is a theoretical computation value for the sequence current component at the end of the transmission line, and iⱼₙ(t) is iⱼₙ₁(t) for the positive sequence current component, iⱼₙ₂(t) for the negative sequence current component and iⱼₙ₀(t) for the zero sequence current component respectively;
iₘ(t) is the sequence current component at the head of the transmission line, and iₘ(t) is iₘ₁(t) for the positive sequence current component, iₘ₂(t) for the negative sequence current component and iₘ₀(t) for the zero sequence current component;
uₘ⁽¹⁾(t)=(uₘ(t)−uₘ(t−Δt))/Δt, and uₘ(t) is uₘ₁(t) for the positive sequence voltage component, uₘ₂(t) for the negative sequence voltage component and uₘ₀(t) for the zero sequence voltage component;
iₘ(t)=[iₘ(t)−iₘ(t−Δt)]/Δt; and
iₘ⁽²⁾(t)=[iₘ(t)−2iₘ(t−Δt)+iₘ(t−2Δt)]/Δt²; and
computing a theoretical current instantaneous value iₒᵤₜ(t) at the end of the transmission line based on the positive sequence current component iⱼₙ₁(t), the negative sequence current component iⱼₙ₂(t) and the zero sequence current component iⱼₙ₀(t) at the end of the transmission line, wherein theoretical three-phase current instantaneous values corresponding to iₒᵤₜ(t) are i_{outA}(t), i_{outB}(t) and i_{outC}(t) respectively.

4. The gradual failure online diagnosis method for the electronic current transformer according to claim 1, wherein both a time interval for collecting the three-phase current instantaneous signals and a time interval for collecting the three-phase voltage instantaneous signals are Δt, and 0.05 ms≦Δt≦0.25 ms.

5. A gradual failure online diagnosis method for an electronic current transformer, comprising:
collecting, at the primary side of each transformer of a substation, three-phase current instantaneous signals output by an electronic current transformer and three-phase voltage instantaneous signals output by an electronic voltage transformer;
computing theoretical three-phase current values i₂ⱼ(t) at the secondary side of the transformer based on the three-phase current instantaneous signals i_{1A}(t), i_{1B}(t), i_{1C}(t) and the three-phase voltage instantaneous signals u_{1A}(t), u_{1B}(t), u_{1C}(t) that are collected at the primary side of the transformer;
collecting three-phase current instantaneous signals i₂(t) output by an electronic current transformer at the secondary side of the transformer;
obtaining a second residual ε_{b}=|i₂(t)−i₂(t)| between the current transformer at the primary side of the transformer and the current transformer at secondary side of the transformer based on the three-phase current instantaneous signals i₂(t) collected at secondary side of the transformer and the computed theoretical three-phase current values i₂ⱼ(t) at secondary side, wherein ε_{b} represents the residual of a b-th transformer, and b represents the number of the transformers, b=1, 2, 3 . . . ; and
comparing the second residual ε_{b} with a second preset threshold ε₀₁, and determining that a gradual failure occurs in the electronic current transformer at the primary side of the b-th transformer or in the electronic current transformer at the secondary side of the b-th transformer if the second residual ε_{b} is greater than or equal to the second preset threshold ε₀₁.

6. The gradual failure online diagnosis method for the electronic current transformer according to claim 5, wherein the computing theoretical three-phase current values i₂ⱼ(t) at the secondary side of the transformer based on the three-phase current instantaneous signals i_{1A}(t), i_{1B}(t), i_{1C}(t) and the three-phase voltage instantaneous signals u_{1A}(t), u_{1B}(t), u_{1C}(t) that are collected at the primary side of the transformer comprises:
computing a magnetic flux density increment ΔB(t) of a excitation branch of the transformer with the following formula (2):
$$Δ B ( t ) = \frac{1}{2 {N}_{1} S} [ {u}_{1} ( t - Δ t ) - {r}_{1} {i}_{1} ( t - Δ t ) - {L}_{1 σ} \frac{{i}_{1} ( t - Δ t ) - {i}_{1} ( t - 2 Δ t )}{Δ t} + {u}_{1} ( t ) - {r}_{1} {i}_{1} ( t ) - {L}_{1 σ} \frac{{i}_{1} ( t ) - {i}_{1} ( t - Δ t )}{Δ t} ] Δ t \qquad ( 2 )$$
where u₁(t) is a voltage instantaneous value at the primary side of the transformer, and three-phase voltage instantaneous values corresponding to u₁(t) are u_{1A}(t), u_{1B}(t), u_{1C}(t);
i₁(t) is a current instantaneous value at the primary side of the transformer, and three-phase current instantaneous values corresponding to i₁(t) are i_{1A}, i_{1B}(t), i_{1C}(t);
r₁ is the winding resistance at the primary side of the transformer;
L_{1σ} is the winding inductance at the primary side of the transformer;
N₁ is the number of primary windings of the transformer; and
S is the cross-sectional area of ferromagnetic material;
performing iterative solution on the following equation by using the magnetic flux density increment ΔB(t) as a step and by utilizing a four-stage four-order Runge-Kutta method, to compute magnetization M(t) at a time instant t:
$$\frac{d M}{d B} = \frac{{M}_{an} - M + k δ c \frac{d {M}_{an}}{d {H}_{e}}}{{μ}_{0} k δ + {μ}_{0} ( 1 - α ) ( {M}_{an} - M + k δ c \frac{d {M}_{an}}{d {H}_{e}} )}$$
$$where \text{:}$$
$$\frac{d {M}_{an}}{d {H}_{e}} = \frac{{M}_{s}}{a} ( \frac{- 1}{{sinh}^{2} ( ( B / {μ}_{0} + ( α - 1 ) M ) / a )} + \frac{1}{{( ( B / {μ}_{0} + ( α - 1 ) M ) / a )}^{2}} ) ;$$
$${M}_{an} = {M}_{s} ( coth ( \frac{B / {μ}_{0} + ( α - 1 ) M}{a} ) - \frac{a}{B / {μ}_{0} + ( α - 1 ) M} ) ;$$
M is the magnetization, Mₛ is saturation magnetization, k is an irreversible hysteresis loss parameter representing a blocking loss effect of the ferromagnetic material, μ₀ is the vacuum permeability, α is an averaging magnetic field coefficient representing the coupling between magnetic domains, a is a parameter representing the shape of an anhysteretic magnetization curve, c is a magnetic domain wall bending coefficient, and
$$δ = \frac{Δ B}{t}$$
is a direction coefficient; and
substituting the magnetic flux density B(t) and the magnetization M(t) at the time instant t into the following formula to compute a theoretical current value at the secondary side of the transformer at the time instant t:
$${i}_{2 j} ( t ) = \frac{{N}_{1}}{{N}_{2}} [ ( B ( t ) / {μ}_{0} - M ( t ) ) l / {N}_{1} - {i}_{1} ( t ) ]$$
where l is the equivalent length of magnetic path, N2 is the number of secondary windings of the transformer, and theoretical three-phase current values corresponding to i₂ⱼ(t) are i_{2jA}(t), i_{2jB}(t) and i_{2jC}(t).

7. The gradual failure online diagnosis method for the electronic current transformer according to claim 5, wherein after it is determined that the gradual failure occurs in the electronic current transformer at the primary side of the b-th transformer or in the electronic current transformer at the secondary side of the b-th transformer, the method further comprises:
performing a Kirchhoff detection on the collected instantaneous values of the electronic current transformers of all branches on a bus, and determining that the electronic current transformer where the gradual failure occurs is located at the bus side of the b-th transformer if the vector sum of current flowing into the bus is greater than ε₀₁, or determining that the electronic current transformer where the gradual failure occurs is located at the non-bus side of the b-th transformer if the vector sum of current flowing into the bus is smaller than or equal to ε₀₁.

8. The gradual failure online diagnosis method for the electronic current transformer according to claim 5, wherein both a time interval for collecting the three-phase current instantaneous signals and a time interval for collecting the three-phase voltage instantaneous signals are Δt, and 0.05 ms≦Δt≦0.25 ms.

9. The gradual failure online diagnosis method for the electronic current transformer according to claim 6, wherein both a time interval for collecting the three-phase current instantaneous signals and a time interval for collecting the three-phase voltage instantaneous signals are Δt, and 0.05 ms≦Δt≦0.25 ms.

10. The gradual failure online diagnosis method for the electronic current transformer according to claim 7, wherein both a time interval for collecting the three-phase current instantaneous signals and a time interval for collecting the three-phase voltage instantaneous signals are Δt, and 0.05 ms≦Δt≦0.25 ms.
